(19) United States
(12) Patent Application Publication
(10) Pub. No.: US 2006/0055012 A1
(43) Pub. Date: Mar. 16, 2006

(54) LED package with zener diode protection circuit

(76) Inventors: Chen-Lun Hsin Chen, Tauyuan (TW); Jung-Hao Hung, Taipei (TW)

Correspondence Address: HungChang Lin, 8 Schindler Ct., Silver Spring, MD, 20903, US

(21) Appl. No.: 11/200,415

(22) Filed: Aug. 10, 2005

(30) Foreign Application Priority Data
Sep. 16, 2004 (TW) 093128152

(51) Int. Cl. H01L 23/02

(52) U.S. Cl. 257/678

(57) ABSTRACT

A light emitting diode (LED) package is fabricated with protection circuit against static electricity. The protection circuit includes series connection of more than one Zener diodes which limit any voltage surge no higher than their breakdown voltage, and is connected in parallel with the LED chip. The breakdown voltage of the protection circuit in either direction is greater than the rated forward or reverse testing voltage. The series connection of the protection circuit can be made through printed circuit submount.

### BACKGROUND OF THE INVENTION

1. Filed of Invention

This invention relates to light emitting diode (LED), in particular to protection circuit against static electricity in a LED package.

2. Brief Description of Prior Art

FIG. 1 shows a traditional LED package. A LED chip 100 is mounted on a lead frame. The LED chip 100 is bonded with aluminum or gold wire 160 to respective positive lead frame 131 and negative lead frame 132 for electrical connection. The lead frames are covered and glued to a reflecting plate 110. The structure is then covered with transparent resin 150. For better protection and light emission, the LED chip is first covered with silicone. Phosphorescent powder may be added to the silicone and/or resin for a blue color LED to emit white light. Such a structure is widely used in cellular phone.

Another widely used back light for cellular phones using LEDs is shown in FIG. 2. A LED chip 100 is mounted on a printed circuit board 120, and is wire bonded with gold or aluminum wire 160 to surface contact leads of the printed circuit board. The structure is covered with transparent glue 150. Phosphorescent powder may be added to the glue to produce white light.

The forgoing LED packages have the common drawback that thee is no protection againstr static electricity. Since blue light LED with additional phosphorescent powder to produce white has now been widely used, yet its susceptibility to static electricity is much worse than other kinds of LED. It can easily be damaged, and the life is limited.

Since the InGaN LED has now become very popular, the protection against static electricity has become an important consideration. Zener diodes have been adopted for protection as shown in FIG. 3. In the LED structure shown in FIG. 1, a Zener diode 140 is mounted on one of the lead frames. The bottom electrode of the Zener diode 140 is bonded to the lead frame, and the top electrode of the Zener diode is wire bonded to the other lead frame. The Zener diode 140 is reversed biased with reference to the LED 100. The Zener diode offers protection when the static electricity voltage reaches the Zener voltage to be clamped. FIG. 4 shows the addition of a Zener diode in the LED package shown in FIG. 2. Similarly, the Zener diode is reversed biased with reference to the LED.

Although the parallel connection of the Zener diode and LED offers protection against static electricity, it prevents the reverse-biased testing of the LED. Reverse-biased testing is a standard test for a LED to sort out defective LEDs. Reverse current is an indication of reliability of the LED. High reverse current indicates defects in the LED which may shorten the life of the LED. When a reverse-biased Zener diode is connected in parallel with the LED as shown in FIG. 3 or FIG. 4, the Zener diode becomes forward-biased when the LED is reversed biased. Thus, the reversed bias test cannot be performed. If the reverse-biased test cannot be conducted for the LED, defective LEDs cannot be sorted out.

Other prior art means for incorporating Zener diode for static electricity protection, such as that disclosed in U.S. Pat. No. 6,642,550, uses a back-to-back Zener diode on the submount for mounting the LED. The purpose is to eliminate a bonding wire, not for reverse bias test nor for protection against transient static electricity when power is turned on or off. Besides, when a Zener diode is mounted on the submount for LEDs, the LED must have a top and a bottom electrode. The Zener diode cannot be incorporated when the two LED electrodes are on the top of the light emitting surface.

### SUMMARY OF THE INVENTION

An object of the present invention is to provide static electricity protection for a LED package. Another object of the invention to provide means for reverse bias testing of a LED package to sort out defective LEDs.

These object are achieved by using two Zener diodes connected back-to-back in parallel with a LED. The positive electrode of the LED is connected to first lead frame by means of wire bonding or conductive glue. Similarly, the negative electrode of the LED is connected to a second lead frame. The two lead frames can be fed from a power supply for light emission. The LED chip is also connected in parallel with a set of even number series connected Zener diodes. At least one the series connected Zener diodes is connected in reverse direction. The breakdown (Zener) voltage of the reverse biased Zener diode is greater than the operating voltage of the LED. The sum of total forward bias voltages of all the forward-biased Zener diodes must be greater than the Zener breakdown voltage, but lower than the acceptable reverse voltage of the LED.

The LED can emit light when forward biased. When the LED is tested under reversed-biased condition, the LED can be applied with a voltage up to the sum of all the Zener voltages of the Zener diodes connected in the same direction as the LED under test. Since the excessive reverse voltage is the main source of damage to a LED, the Zener diodes can provide protection to the LED.

In another improved design, the sum of all the reverse-biased Zener diodes breakdown voltages and the forward biased voltage the LEDs is designed to be lower than the maximum allowable forward biased voltage of the LED, so that the series Zener diodes clamps any transient or steady-state forward-biased voltage to protect the LED.

In a further improvement, if the foregoing Zener diodes are changed totally or partly to different color LEDs, then the color LEDs provides a warning signal.

Since the protective circuit is planted within the LED structure, this provides high degree of protection, during production phase or operation. Whether static electricity is due to environment or due to operation, this invention provides a highly reliable light source.

### BRIEF DESCRIPTION OF THE DRAWINGS

FIG. 1 shows a prior art LED package.

FIG. 2 shows a second prior art LED package.

FIG. 3 shows a prior art static electricity protection structure for FIG. 1.

FIG. 4 shows a prior art static electricity protection structure for FIG. 2.

FIG. 5 shows the basic static electricity production structure of the present invention.

FIG. 6 shows the voltage-current characteristic of a Zener diode

FIG. 7 shows a second embodiment of the present invention.

FIG. 8 shows the equivalent circuit of the structure shown in FIG. 7.

FIG. 9 shows a third embodiment of the present invention.

### DETAILED DESCRIPTON OF THE INVENTION

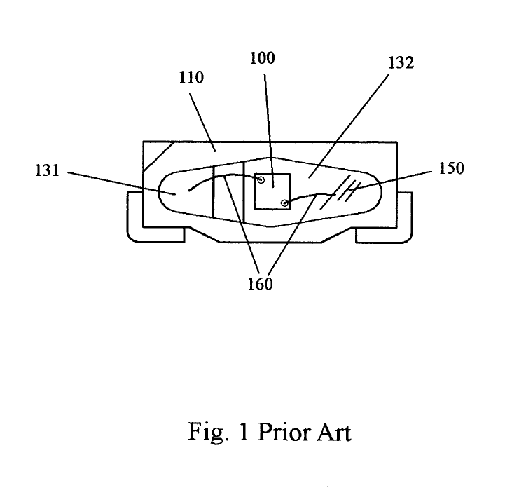

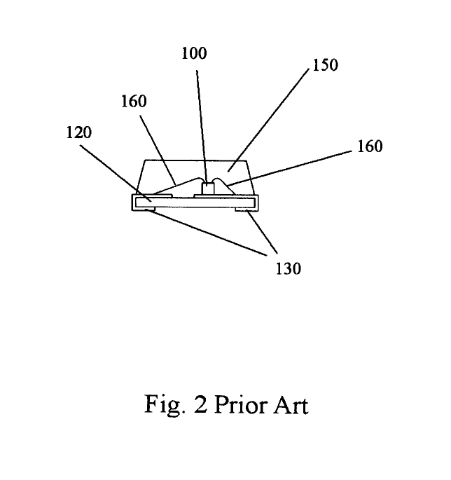

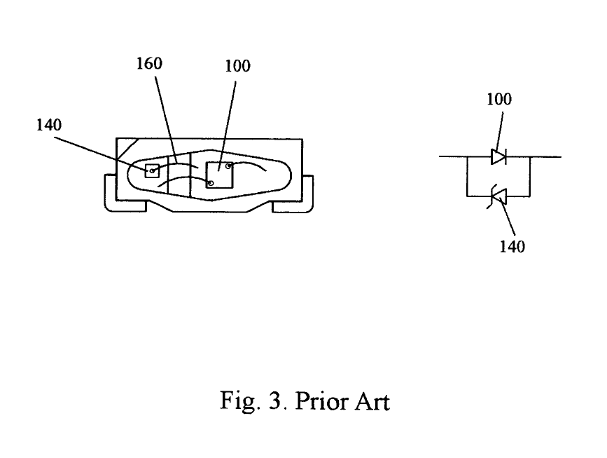

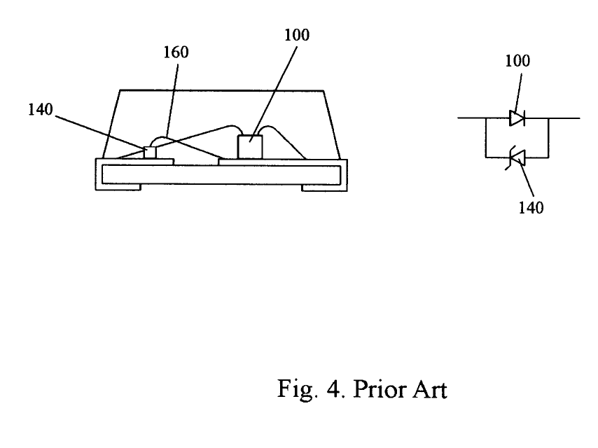

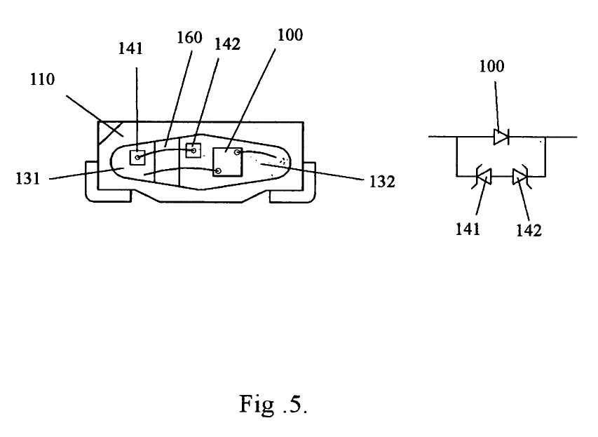

The first embodiment of the present invention is shown in FIG 5. It shows the improvement over FIG. 1. A blue LED chip 100 is mounted on a negative lead frame 132, which is supported on a reflecting plate 110 as a structure. One of the top electrodes of the LED chip 100 is wire bonded to the negative lead frame 132, which is also supported on the substrate 110, and another top electrode of the LED 100 is wire bonded to the positive lead frame 131. Over the negative lead frame 132 is attached a p-type Zener diode chip 141 with silver paste, having a breakdown voltage of 6 V. Over the positive lead frame 131 is another p-type Zener diode chip 142 with silver paste having a breakdown voltage of 12 V. The two Zener diodes are connected back-to-back to each other using gold or aluminum bonding wires 160 to the bonding pads. The devices are then covered silicones with added phosphorescent powder to produce white light. The substrate can be printed circuit board, a ceramic or silicon composite

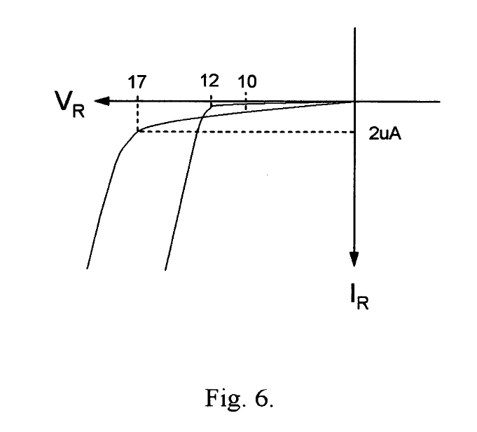

FIG. 6 shows the reverse voltage vs current characteristic of a Zener diode. When the LED is tested under reverse bias condition to 10 V, the voltage is less than the break down voltage of the Zener diode and the reverse characteristic can be accurately measured. Although the Zener diode may have some leakage, the leakage current is much less than the specified current limit of 10 uA. However, if the supply voltage is abnormal and static electricity present is higher than specified limit (say 17V), the Zener diode conducts to protect the LED.

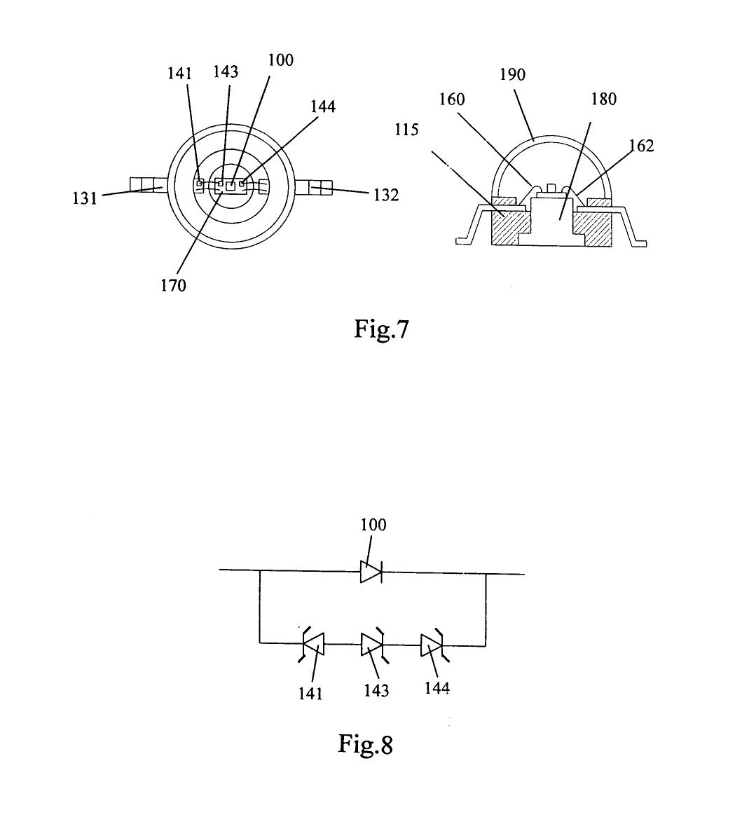

FIG. 7 is another embodiment of the present invention. A positive lead frame 131 and a negative lead frame are embedded in a plastic shell 115, exposing a region for wire bonding. A LED 100 is attached to a submount 170 of printed circuit board, ceramic circuit board, silicon substrate, or their composite, which has printed wiring for connection to the two bottom electrodes of the LED 141. The submount 170 is attached to a heat sinking pedestal 180, which is wrapped around by the plastic shell 115 except the bottom surface for cooling. The printed connections to the electrodes of the LED 141 are wire bonded to the respective positive lead frame and negative lead frame. On the positive lead frame 131 is also bonded with silver paste a p-type Zener diodes 141 with a breakdown voltage of 6V. On the submount 170 is also bonded with silver paste another p-type Zener diode 143, which is wire-bonded with gold or aluminum wire to the top bonding pad of the p-type Zener diode 141 on the positive lead frame 131. On the negative lead frame is also bonded with silver paste an n-type Zener diode chip 144 with a breakdown voltage of 6 V, and wire-bonded with gold or aluminum wire to the bonding pad on the negative lead flame 132. The chips are covered with silicone and then a transparent plastic cover 190 at the outer layer.

The equivalent circuit of the LED package is shown in FIG. 8. When the LED chip is tested with reverse biased voltage of 10V, this voltage is lower than the series breakdown voltage of two Zener diodes and the LED is properly tested without being shunted. When the reverse voltage exceeds the allowable reverse voltage (say 17 V) due to power supply fluctuation or static electricity, the two Zener diodes become conductive, thus protecting the LED.

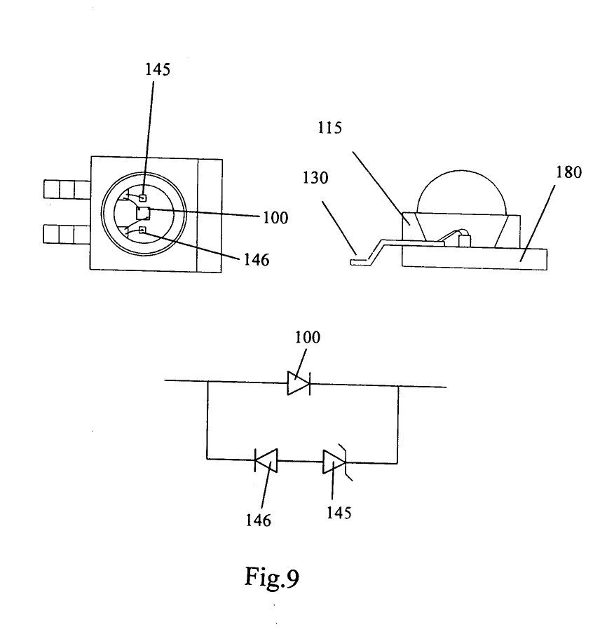

FIG. 9 show a third embodiment of the invention. A blue LED 100 is mounted over a heat sink 180 and wrapped over by a plastic shell 115, which forms a unitary structure with the bottom of the heat sink exposed. The LED chip 100 is attached to the heat sink and is wire bonded with gold or aluminum wires to respective positive and negative lead flames 130. An n-type Zener diode 145 with a breakdown voltage of 5V and a red LED 146 are also mounted on the heat sink 180. The red LED 145 is wire bonded to the positive lead flame with gold or aluminum wire and the Zener diode 145 is wire bonded to the negative lead frame. (How are LED 146 and Zener diode 145 connected? not shown) The equivalent circuit of the structure is shown at the bottom of FIG. 9. When the reverse voltage exceed 6V due to static electricity or other reason, the red LED 116 light up as a warming.

While the foregoing embodiments have only one light emitting diode, the protective schemes can also be applied a LED chip having a plurality of LEDs in series, in parallel or in series-parallel combination.

While the preferred embodiments have been described, it will be apparent to those skilled in the art that various modifications may be made without departing from the spirit of the present invention. Such modifications are all within the scope of the present invention.

1. A light emitting diode (LED) package, comprising:
a LED chip, having a positive electrode and a negative electrode;
a lead fame having at least two independent areas, each coupled to said positive electrode and said negative electrode; and
a protective circuit in parallel connection with said LED, having at least two series connected diodes, at least one of the diodes being polarized in the same direction as the LED and at least one of the diodes being polarized in opposite direction to the LED,
wherein the sum of breakdown voltage of all said diodes being polarized in opposite direction as the LED is higher than forward working voltage of said LED, and the sum of the breakdown voltage of all said diodes polarized in the same direction as the LED is higher than the testing voltage used in a bias testing, and meanwhile less than the allowable reverse voltage of the LED.

2. The LED package as described in claim 1, wherein the breakdown voltage of all the diodes polarized in opposite direction to said LED is less than the maximum allowable forward voltage of the LED.

3. The LED package as described in claim 1, wherein said diodes in said protective circuit is selected from the group consisting of light emitting diode and Zener diode.

4. The LED package as described in claim 1, further comprising a substrate for mounting said chip, said substrate being made of a material selected from the group consisting of printed circuit board, ceramic, and silicon, and bonded to or glued to said lead frames.

5. The LED package as described in claim 1, wherein said LED chip is mounted on said lead frame.

6. The LED package as described in claim 4, wherein said submount is an independent heat sink, having bottom exposed for heat removal.

7. The LED package as described in claim 1, wherein said LED chip is mounted on an independent metal heat sink with bottom exposed for cooling, and is wire bonded to two said areas of said lead frames for connections respectively to the positive electrode and the negative electrode of said LED.

8. A light emitting diode package, comprising:
a light emitting chip, having a positive electrode and a negative electrode
a lead frame having at least two independent areas each coupled to said positive electrode and said negative electrode;
a first lead frame and a second lead frame;
a plurality of series connected or parallel connected or the combination of LEDs, having its positive electrode coupled to said first lead frame and having its negative electrode coupled to said second lead frame.
a protective circuit in parallel connection with said LED chip, having
more than two diodes, at least one of the diodes being polarized in the same direction as the LED chip and at least one of the diodes polarized in the opposite direction to the :LED chip, wherein
the sum of breakdown voltages of all said diodes polarized in opposite direction to the LED chip is higher than the forward working voltage of said LED chip, and
the sum of breakdown voltage of all said diodes polarized in the same direction as the LED chip is higher than the testing voltage used in a bias testing, and meanwhile less than the allowable reverse voltage of the LED chip.

9. The LED package as described in claim 8, wherein the total reverse breakdown voltages of all the diodes in the protective circuit polarized in opposite direction as the LED chip is less than the allowable forward bias voltage of the LED chip.

10. The LED package as described in claim 8, wherein the diodes in the protective circuit are Zener diode, light emitting diode, or combination of the two.

11. The LED package as described in claim 8, further comprising a submount for mounting said chip, said substrate being made of material selected from the group consisting of printed circuit board, ceramic and silicon

12. The LED package as described in claim 8, wherein the LED is mounted on said lead frame.

13. The LED package as described in claim 12, wherein said LED chip is mounted on an independent metal heat sink with exposed bottom surface for removing heat generated from said diode.

14. The LED package as described in claim 11, further comprising an independent metal heat sink carrying said submount, wherein said metal heat sink diffuses heat from its exposed bottom side, and the two electrodes of said diode are wire bonded to respectively of said two lead frames.
